(19) United States
(12) Patent Application Publication
(10) Pub. No.: US 2012/0048359 A1
(43) Pub. Date: Mar. 1, 2012

(54) MULTI-JUNCTION SOLAR CELLS WITH AN APLANATIC IMAGING SYSTEM AND COUPLED NON-IMAGING LIGHT CONCENTRATOR

(75) Inventors: Roland Winston, Merced, CA (US); Jeffrey M. Gordon, Atwater, CA (US)

(73) Assignee: The Regents of the University of California, Oakland, CA (US)

(21) Appl. No.: 13/287,919

(22) Filed: Nov. 2, 2011

Related U.S. Application Data
(63) Continuation of application No. 11/084,882, filed on Mar. 21, 2005.

(51) Int. Cl. H01L 31/0232; H01L 31/06

(52) U.S. Cl. 136/255; 136/259

(57) ABSTRACT

An optical system for a solar energy device to produce electrical energy. The optical system includes an aplanatic optical imaging system, a non-imaging solar concentrator coupled to the aplanatic system and a multi-junction solar cell to receive highly concentrated light from the non-imaging solar concentrator.

### BACKGROUND OF THE INVENTION

The present invention is concerned with a multi junction solar cell employing an optical system which provides extremely high solar flux to produce very efficient electrical output. More particularly, the invention is directed to a solar energy system which combines a non-imaging light concentrator, or flux booster, with an aplanatic primary and secondary mirror subsystem wherein the non-imaging concentrator is efficiently coupled to the mirrors such that imaging conditions are achieved for high intensity light concentration onto a multi junction solar cell.

Solar cells for electrical energy production are very well known but have limited utility due to the very high Kwh cost of production. While substantial research has been ongoing for many years, the cost per Kwh still is about ten times that of conventional electric power production. In order to even compete with wind power or other alternative energy sources, the efficiency of production of electricity from solar cells must be drastically improved.

### SUMMARY OF THE INVENTION

Aplanatic optical imaging designs are combined with a non-imaging optical system to produce an ultra-compact light concentrator that performs at etendue limits. In a multi-junction solar cell system the aplanatic optics along with a coupled non-imaging concentrator produce electrical output with very high efficiency. In alternate embodiments a plurality of conventional solar cells can be used in place of a multi-junction cell.

A variety of aplanatic and planar optical systems can provide the necessary components to deliver light to a non-imaging concentrator which forms a highly concentrated light output to a multi-junction solar cell. In one embodiment a secondary mirror is co-planar with the entrance aperture, and the exit aperture is co-planar with the vertex of the primary mirror. It is readily shown on general grounds that for the most compact imaging system with a primary and secondary mirror the ratio of depth to diameter is 1:4. FIG. 1 exemplifies this relation. In a preferred embodiment the inter mirror space is filled with a dielectric with index of refraction, n, such that the numerical aperture (“NA”) is increased by a factor of n. A non-imaging light concentrator is disposed at the exit aperture of the primary mirror wherein the non-imaging concentrator is a θ₁/θ₂ concentrator with θ₁, chosen to match the NA of the imaging stage of the system (sin θ₁=NA,/n) while θ₂ is chosen to satisfy a subsidiary condition, such as maintaining total internal reflection (“TIR”) or limiting the angle of irradiance on the multi junction solar cell, or allowing radiation to emerge to accommodate a small air gap between the concentrator and the multi-junction solar cell (or the light source for the illuminator form of the invention described hereinafter).

This system with its combination of elements enables employment of the highly efficient multi-junction solar cell such that a very intense solar flux can be input to the solar cell by the non-imaging light concentrator which is coupled to an aplanatic and planar optical subsystem. While multi junction solar cells are about 100 times more expensive than conventional cells on an area basic, the system described herein can provide highly concentrated sunlight, such as at least about several thousand suns, so that the multi-junction cell cost becomes very attractive commercially. The optical system therefore provides the light intensity needed to achieve commercial effectiveness for solar cells. It should also be noted that the above-described optical system also can be employed as an illuminator with a light source disposed adjacent the light transformer.

Objectives and advantages of the invention will become apparent from the following detailed description and drawings described hereinbelow.

### BRIEF DESCRIPTION OF THE DRAWINGS

FIG. 1 illustrates an aplanatic optical system with an associated non-imaging concentrator coupled to a multi-junction solar cell; and

FIG. 2 is a detail of the non-imaging concentrator.

### DETAILED DESCRIPTION OF THE PREFERRED EMBODIMENTS

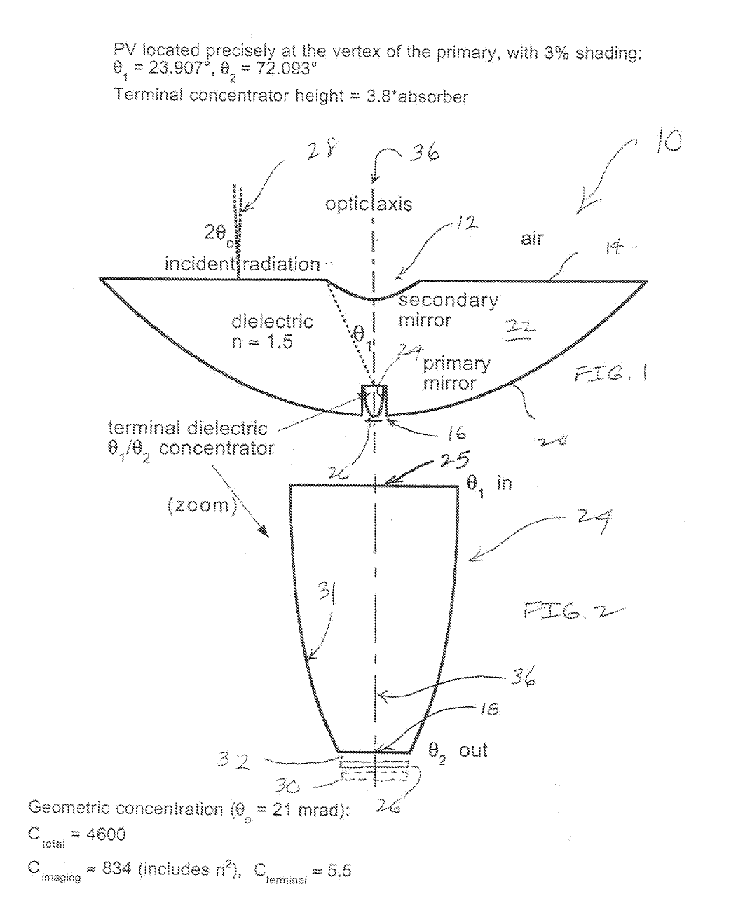

An optical system 10 constructed in accordance with one embodiment of the invention is shown in FIG. 1. A secondary mirror 14 is co-planar with an entrance aperture 12 of a primary mirror 20. The focus of the combination of the primary mirror 20 and the secondary mirror 14 resides at the center of an entrance aperture 25 of a nonimaging concentrator 24 best seen in FIG. 2 (described below in detail). The final flux output which may be considered the nominal “focus” of the optical system 10 of the primary mirror 20, secondary mirror 12, and the nonimaging concentrator 24 is produced at the exit aperture 16 which intersects the vertex 18 of the primary mirror 20. The vertex 18 is a point located at the intersection of the primary mirror 20 and the optic axis 26. The primary mirror 20 is interrupted to accommodate the concentrator 24. In the preferred embodiment, the vertex 18 is also at the center of the exit aperture 32. Solar radiation uniformly incident over angle 2θ₀ (the convolution of the solar disk with optical errors) is concentrated to the focal plane where it is distributed over angle 2θ₁. If we fill intervening space with dielectric 22 of index of refraction (n), the numerical aperture (NA) is increased by n. For typical materials, this is a factor between about 1.4 and 1.5 which is significant since the corresponding concentration (for the same field of view) is increased by n²˜2.25 (provided the absorber is optically coupled to a light transformer or a concentrator 24). In a preferred embodiment, the non-imaging concentrator 24 is disposed at the exit aperture 16 and has another entrance aperture 25. This concentrator 24 is most preferably a θ₁/θ₂ non-imaging concentrator where θ₁ is chosen to match the numerical aperture (NA₁) of the imaging stage portion of the optical system 10 with the primary mirror 20 and the secondary mirror 14 where (sin θ₁)=NA₁/n). The θ₂ is chosen to satisfy a subsidiary condition, such as maintaining total internal reflection (TIR) or limiting angles of irradiance onto a multi-junction cell 26, or allowing radiation to emerge to accommodate a small air gap between the concentrator 24 and the multi-junction solar cell 26 (or the light source 30 for the illuminator form of the invention). The concentration or flux boost of the terminal stage approaches the fundamental limit of (sin θ₂/sin θ₁)². The overall concentration can approach the extendue limit of (n/sin θ₀)² where sin θ₀=n sin θ₁. In an alternate embodiment, the multi junction cell 26 can be a conventional small solar cell. In another embodiment the non-imaging concentrator 24 can be a known tailored non-imaging concentrator.

In the optical system 10, both the entrance aperture 14 and the exit aperture 16 are substantially flat, making this a straightforward case to analyze. In fact, the preferred optical system 10 has a design which falls under the category of well-known θ₁/θ₂ non-imaging concentrators. The condition for TIR is

θ₁+θ₂≦π−2θ_{c} (1)

where θ_{c} is the critical angle, arc sin (1/n).

In many cases of practical importance the TIR condition is compatible with limiting the irradiance angle to reasonable prescribed values. Since the overall optical system 10 is near ideal, the overall NA is NA₂=n sin (θ₂)≅n when θ₂ is close to π/2. In an alternative embodiment a reflective surface 31 of the concentrator 24 need not be such that TIR occurs. In this alternative embodiment the exterior of the θ₁/θ₂ concentrator, the reflective surface 31 can be a silvered surface, thereby not restricting θ₂ but incurring an optical loss of approximately one additional reflection (˜4%).

The overall optical system 10 is near-ideal in that raytraces of both imaging and nonimaging forms of the concentrator 24 reveal that skew ray rejection does not exceed a few %. Co-planar designs can reach the minimum aspect ratio (f-number) of ¼ for the selected concentrator 24 that satisfies Fermat's principle of constant optical path length. By tracing paraxial rays from the two extremes of (1) the rim of the primary mirror 20 and (2) along optic axis 36, and stipulating constant optical path length to the focus, it is straightforward to show that (a) the distance from the primary's vertex 18 to the entrance aperture 12 cannot be less than ¼ of the entry diameter, and (b) the compactness limit requires co-planarity. Because such high-flux devices will ultimately be constrained by dielectric thickness (volume), we can describe various embodiments for the preferred co-planar units.

The design choice for θ₁ has considerable freedom despite the co-planarity constraint. The most practical design when accounting for fragility, cell attachment and heat sinking would appear to site the PV absorber at the vertex 18 of the primary mirror 20. For a design so constrained, there is a tradeoff between increasing θ₁ and shading by the secondary mirror 14. For example, for shading ≦3%, θ₁≦24°. Taking n≈1.5, we have θ_{c}≈42°. Then from Eq (1), θ₁+θ₂≦96°. The illustrative case in FIG. 1 has θ₁=24°, θ₂=72° and 3% shading, with (n sin (θ₂))²=2.0 being quite close to the etendue limit. Perhaps the simplest terminal concentrator 24 is a frustrum (truncated V-cone). However, the frustrum depth needed to realize the maximum concentration enhancement is substantially greater than the corresponding θ₁/θ₂ design (for the parameter ranges considered here) if both light leakage and excessive ray rejection are to be avoided.

Manufacturing simplicity and cost could militate against the optical coupling of the cell 26 to the concentrator 24. In this case, light is extracted into air and then projected onto the cell 26. The integral ultra-compact design of FIG. 1 is still applicable, including siting the cell 26 at the vertex 18 of the primary mirror 20. The terminal concentrator 24 must then have θ₂<θ_{c} in order to avoid ray rejection by TIR. Accommodating its relatively greater depth (i.e., retaining the same cell position) requires redesigning the imaging dielectric concentrator 24 with its focus closer to the secondary mirror 14. The corresponding &endue limit for achievable concentration is reduced by a factor of n² to))(1/sin (θₒ))².

All dielectrics that are transparent in some wavelength range will have dispersion, a consequent of absorption outside the transparent window. Even for glass or acrylic, where the dispersion is only a few percent, this significantly limits the solar flux concentration achievable by a well-designed Fresnel lens to ≈500 suns. For a planar dielectric form of the concentrator 24, the only refracting interface is the entrance aperture 12, normal to an incident beam 28. At the interface (the entrance aperture 14) angular dispersion is,

δθ=−tan (θ)δn/n (2)

which is completely negligible since the angular spread of the incident beam 28 is <<1 radian. The dielectric optical system 10 is for practical purposes achromatic. In fact, Equation (2) indicates some flexibility in design. The dielectric/air interface (the entrance aperture 12) need not be strictly normal to the beam. A modest inclination is allowable, just as long as chromatic effects, as determined by Equation (2) are kept in bounds.

Non-imaging devices, such as the concentrator 24, can operate very well at the diffraction limit where the smallest aperture is comparable to the wavelength of light. This is well beyond what would be required for a photoelectric concentrator, but can be useful in detectors at sub-millimeter wavelengths, which is a plausible application for the embodiments herein. With the wide range of scales available, the power densities on the multi junction cell 26 are about 1 watt (electric) per square mm, providing care is taken in designing the tunnel diode layers separating the junctions. This would imply a solar flux≈3330 suns with a geometric concentration Cg≈4600 (taking a 30% system efficiency to electricity from a nominally 40% efficient cell which accounts for losses from mirror absorption, Fresnel reflections, attenuation in the dielectric, shading, cell heating, a few % ray rejection, and a modest dilution of power density in order to accommodate the full flux map in the focal plane).

With a 1 mm diameter cell 26, the concentrator 24 of FIG. 1 would be 68 mm in diameter with a maximum depth of 17 mm and a mass per unit area equivalent to a flat slab 8.5 mm thick. Clearly, considerably thinner forms of the concentrator 24 can be designed (for the same cell size) with lower concentration and commensurately reduced power generation densities.

The corresponding angular field of view is

θₒ≈Sin (θₒ)=n sin (θ₂)/√C_{g} (3)

which is ≈21 mrad for the above example, sufficient to accommodate the convolution of the inherent sun size (4.7 mrad) with liberal optical tolerances. A tighter optical tolerance would generate a smaller spot on the cell 26. Fortunately, experiments have shown that cell performance can be relatively insensitive to such flux inhomogeneities even at flux levels of thousands of suns. Raytrace simulations of the air-filled concentrator 24 indicated that θₒ can reach 20 mrad before second-order aberrations start to reduce flux concentration noticeably. The corresponding threshold here would be nθₒ≈30 mrad. The cell 26 itself might be one or several mm². Since the planar concentrator volume grows as the cube of the cell size, this is an engineering optimization. In any case, the heat rejection load of a few watts can be dissipated passively such that temperature increases do not exceed around 30 K.

So far, the optical system 10 has been viewed as axisymmetric, with circular apertures and circular ones of the cell 26. Given the relative ease of reaching high flux levels, maximizing collection efficiency is paramount, including concentrator packing within modules. Also, given that economic fabrication and cutting techniques yield square ones of the cell 26, one could consider concentrating from a square entrance aperture onto a square target. Producing the same power density at no loss in collection or cell efficiency then ordains increasing geometric concentration by a factor of (4/π)²≈1.62 (or one could dilute power density at fixed geometric concentration).

High-NA₁ co-planar designs are possible, but only when the focus is well recessed within the primary. Eq (1)—and hence TIR—cannot be satisfied, so the terminal concentrator 24 would need to be externally silvered (and no terminal booster is required as NA₁→1). The dielectric 22 in the central region can be removed while preserving the factor of n² amplification in concentration. Cell attachment and heat sinking would be considerably more problematic than in the design of FIG. 1.

The planar all-dielectric optical system 10 presented here embodies inexpensive high-performance forms that should be capable of (a) generating about 1 W from advanced commercial 1 mm² solar cells 26 at flux levels up to several thousand suns, (b) incurring negligible chromatic aberration even at ultra-high concentration, (c) passive cooling of the cell 26, (d) accommodating liberal optical tolerances, (e) mass production with existing glass and polymeric molding techniques, and (f) realizing the fundamental compactness limit of a ¼ aspect ratio.

In addition to the embodiment described hereinbefore, in reverse the optical system 10 can be a compact collimator performing very near the etendue limit. A light source 30 (shown in phantom in FIG. 2), positioned near the “exit” aperture 32 of the non-imaging concentrator 24, can be a light emitting diode. In general the optical system 10 can be a light transformer, either collecting light for concentration downstream from the non-imaging concentrator 24 or generating a selected light output pattern in the case of the light source 30 dispersed near the “exit” aperture 32 of the non-imaging concentrator (now an “illuminator”) 24 which would then output light in the desired manner. Such collimators would find many applications in illumination systems to create a desired pattern.

The following non-limiting examples are merely illustrative of the design of the system.

### EXAMPLE 1

The optical space is filled with the dielectric 22, i.e., the planar non-imaging concentrator 24 resembles a slab of glass. The multi-junction technology lends itself to small solar cell sizes. This size relationship works better since the high current has a shorter distance to travel, mitigating internal resistance effects. Consequently, it is preferable that the cells 26 are in the one to several square mm sizes. The design choice for NA₁ has considerable freedom, a trade-off with shading by the secondary mirror 12, but is typically in the range of about 0.3 to 0.4. Taking n.≈1.5, a typical value for glasses (and plastics) we have θ_{c}42°. Then from Equation (1), (θ₁+θ₂)≦96°, we take NA₁=0.4n, θ₁≈23.5° and θ₂ can be as large as 72°, a perfectly reasonable maximum irradiance angle on the multi junction solar cell 26. At the same time, NA₂≈0.95n, within 5% of the etendue limit.

### EXAMPLE 2

In another embodiment the non-imaging optical concentrator (or illuminator) is a cylinder with θ₁=θ₂. The angular restrictions imposed depend on the desired conditions. If TIR is desired and the solar cell is optically coupled to the multi-junction solar cell 26 (or the light source 30 for the illuminator), θ₁ should not exceed (90°−θ_{c})≈48°. If TIR is desired and there is a small air gap between the concentrator and the multi-junction solar cell 26 (or the light source 30 for the illuminator), θ₁ should not exceed θ_{c}≈42°. If the cylinder is silvered and the concentrator is optically coupled to the multi junction solar cell 26 (or the light source 30 for the illuminator) there is no restriction. If the cylinder is silvered and there is a small air gap between the concentrator and the multi-junction solar cell 26 (or the light source 30 for the illuminator), θ₁ should not exceed θ_{c}≈42°.

### EXAMPLE 3

In another embodiment, radiation is allowed to emerge to accommodate a small air gap between the concentrator and the multi junction solar cell 26 (or the light source 30 for the illuminator), then θ₁ should not exceed θ_{c}≈42°. Let θ₂=39° and θ₁=23.5° as before. Then NA₂=n sin (39°)=0.94, which is within 6% of the etendue limit.

What is claimed is:

1. A solar energy system, comprising:
an aplanatic optical imaging system, wherein the imaging system includes a primary mirror and a secondary mirror;
a non-imaging solar concentrator to collect light from the aplanatic optical imaging system; and
a solar cell receiving light from the non-imaging solar concentrator, the solar cell creating an electrical output.

2. The solar energy system as defined in claim 1 wherein the solar cell comprises a multi-junction solar cell.

3. The solar energy system as defined in claim I wherein the aplanatic optical imaging system includes at least one of the secondary mirror with a co-planar entrance aperture and the primary mirror which includes an exit aperture centered by the vertex.

4. The solar energy system as defined in claim 1 wherein the aplanatic optical imaging system comprises a dielectric disposed between the primary mirror and the secondary mirror.

5. The solar energy system as defined in claim 4 wherein the dielectric is selected from the group consisting of air and a material having an index of refraction, n, of about 1.4 to 1.5.

6. The solar energy system as defined in claim 1 wherein the non-imaging solar concentrator comprises a θ₁/θ₂ non-imaging concentrator.

7. The solar energy system as defined in claim 6 wherein the θⱼ/θ₂ non-imaging concentrator is selected by θᵢ chosen to match a numerical aperture of the aplanatic optical imaging system.

8. The solar energy system as defined in claim 1 wherein an exit aperture of both the primary mirror and the secondary mirror are substantially flat.

9. The solar energy system as defined in claim 1 wherein the non-imaging concentrator provides total internal reflection.

10. The solar energy system as defined in claim 1 wherein the non-imaging concentrator includes a silvered reflective surface.

11. The solar energy system as defined in claim 1 wherein an exit aperture of the nonimaging solar concentrator is positioned substantially flush with an exit aperture of the primary mirror.

12. The solar energy system as defined in claim 11 wherein the non-imaging solar concentrator comprises a tailored reflecting surface.

13. The solar energy system of claim 1 wherein the aplanatic optical imaging system and non-imaging solar concentrator are axisymmetric.

14. The solar energy system of claim 1 wherein the solar cell is positioned substantially flush with an exit aperture of the primary mirror.
